(19) United States
(12) Patent Application Publication
(10) Pub. No.: US 2022/0121378 A1
(43) Pub. Date: Apr. 21, 2022

(54) PROGRAMMABLE DEVICE

(71) Applicant: Mitsubishi Electric Corporation, Chiyoda-ku, Tokyo (JP)

(72) Inventor: Takumi HOSHI, Chiyoda-ku, Tokyo (JP)

(73) Assignee: Mitsubishi Electric Corporation, Chiyoda-ku, Tokyo (JP)

(21) Appl. No.: 17/417,687

(22) PCT Filed: Feb. 12, 2019
(86) PCT No.: PCT/JP2019/004858

§ 371 Date: Jun. 23, 2021

(51) Int. Cl. G06F 3/06

(52) U.S. Cl. CPC G06F 3/0619; G06F 3/0629; G06F 3/0673

(57) ABSTRACT

A programmable device includes: a programmable logic element group which includes a plurality of programmable logic elements; and a configuration memory to store logic information items for circuits configured by programmable logic elements. The configuration memory includes first logic information that configures a first error detector with a programmable logic element. The first error detector examines any logic information, other than first logic information.

### TECHNICAL FIELD

The present invention relates to a programmable device.

### BACKGROUND ART

An advantage of an static random access memory (SRAM) programmable device which includes a configuration memory configured of a SRAM is that the circuit can be programmed unlimited number of times by rewriting the logic of the configuration memory.

However, an SRAM programmable device is prone to soft errors in which logic information in a configuration memory is destroyed by neutron rays raining down on the SRAM programmable device from space. There is a need for a secure system which detects destruction of logic information in the configuration memory and normalizes the system or causes the system to transition to a secure operational mode.

The device disclosed in PTL 1 (Japanese Patent No. 5699057) detects destruction of logic information by making use of the fact that a control circuit is caused to malfunction by the destruction of the logic information that is due to soft errors, and results in outputting a false result. The method of detection according to PTL 1 is as follows:

A control circuit having the same functionality is configured in three types of programmable devices. Output values of the three types of control circuits are observed and destruction of logic information is detected by majority decision. After the detection of the destruction of logic information, the device overwrites the logic information in the configuration memory with normal logic information, thereby normalizing the operation of the control circuit.

### CITATION LIST

### Patent Literature

PTL 1: Japanese Patent No. 5699057

### SUMMARY OF INVENTION

### Technical Problem

However, the device disclosed in PTL 1 (Japanese Patent No. 5699057) requires tripling of a control circuit, resulting in the circuit size being tripled.

Therefore, an object of the present invention is to provide a small-circuit size, programmable device which detects destruction of logic information.

### Solution to Problem

A programmable device according to the present invention includes a plurality of programmable logic elements, and a configuration memory to store logic information for circuits configured by the plurality of programmable logic elements. The configuration memory includes first logic information that configures a first error detector programmable logic elements with programmable logic elements. The first error detector examines any logic information, other than first logic information.

### Advantageous Effects of Invention

According to the present invention, since the first error detector, configured with the first logic information, examines logic information other than the first logic information, the programmable device, while it has a small circuit size, can detect destruction of logic information.

### BRIEF DESCRIPTION OF DRAWINGS

FIG. 1 is a diagram showing a configuration of a programmable device 100 according to Embodiment 1.

FIG. 2 is a diagram showing logic information items stored in a configuration memory 120 and circuits configured with these logic information items.

FIG. 3 is a diagram showing correspondences between logic information items in the configuration memory and parity bits in a first error detection bit memory 141 and a second error detection bit memory 151, according to Embodiment 1.

FIG. 4 is a flowchart illustrating a procedure for causing programmable device 100 to operate as a control device.

FIG. 5 is a flowchart illustrating a procedure for detecting an error in logic information in configuration memory 120.

FIG. 6 is a diagram showing a configuration of a programmable device 100 according to Embodiments 2.

FIG. 7 is a diagram showing correspondences between logic information items in a configuration memory and parity bits in an error detection bit memory 170, according to Embodiments 2.

FIG. 8 is a diagram showing a configuration of a programmable device 100 according to Embodiments 3.

FIG. 9 is a diagram showing correspondences between logic information items in a configuration memory and parity bits in an error detection bit memory 170, according to Embodiments 3.

FIG. 10 is a diagram showing a configuration of a programmable device 100 according to Embodiments 4.

FIG. 11 is a diagram showing correspondences between logic information items in a configuration memory and parity bits in an error detection bit memory 170, according to Embodiments 4.

### DESCRIPTION OF EMBODIMENTS

Hereinafter, embodiments will be described, with reference to the accompanying drawings.

### Embodiment 1

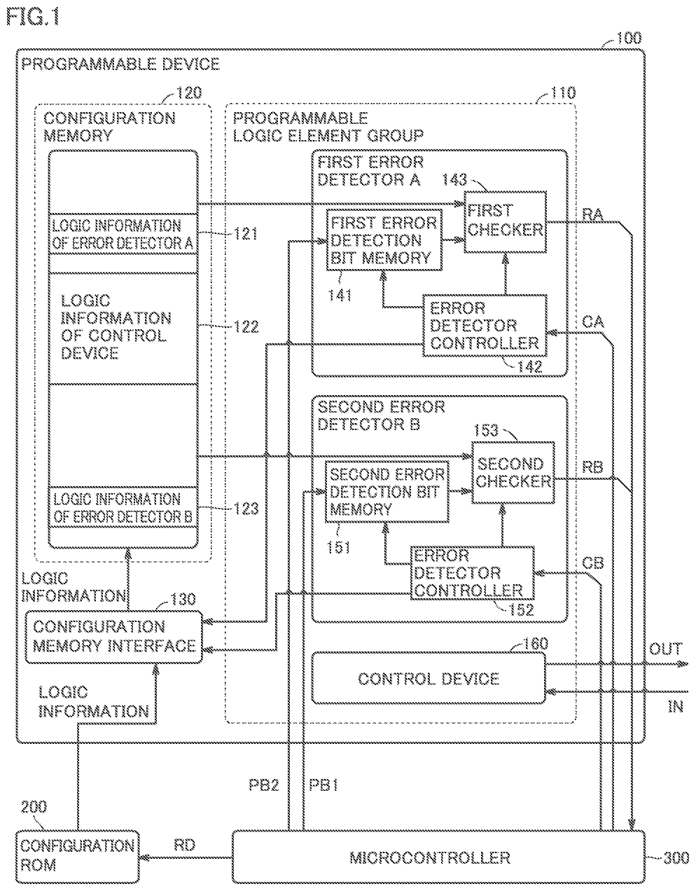

FIG. 1 is a diagram showing a configuration of a programmable device 100 according to Embodiment 1.

Programmable device 100 includes a configuration memory 120, a programmable logic element group 110, and a configuration memory interface 130.

Configuration memory 120 stores logic information for circuit that are configured by programmable logic elements.

Programmable logic element group 110 includes multiple programmable logic elements.

Configuration memory interface 130 receives logic information stored in a configuration read only memory (ROM) 200, and writes the logic information to configuration memory 120. A microcontroller 300 controls programmable device 100 so that the logic information stored in configuration ROM 200 is transferred to programmable device 100.

Microcontroller 300 outputs a parity bit group PB1 for logic information items in first examination area 161 to a second error detection bit memory 151. Microcontroller 300 outputs a parity bit group PB2 for logic information items in second examination area 162 to a first error detection bit memory 141.

Programmable logic elements in programmable logic element group 110 configure a first error detector A, a second error detector B, and a control device 160.

First error detector A includes a first error detection bit memory 141, a first checker 143, and an error detector controller 142. Error detector controller 142 receives a control signal CA from microcontroller 300, and controls first error detection bit memory 141 and first checker 143. First checker 143 outputs a signal RA representing a result of examination to microcontroller 300. Error detector controller 142 can also control configuration memory interface 130.

Second error detector B includes a second error detection bit memory 151, a second checker 153, and an error detector controller 152. Error detector controller 152 receives a control signal CB from microcontroller 300, and controls second error detection bit memory 151 and second checker 153. Second checker 153 outputs a signal RB representing a result of examination to microcontroller 300. Error detector controller 152 can also control configuration memory interface 130.

Control device 160 externally receives an input signal IN. Control device 160 externally outputs an output signal OUT.

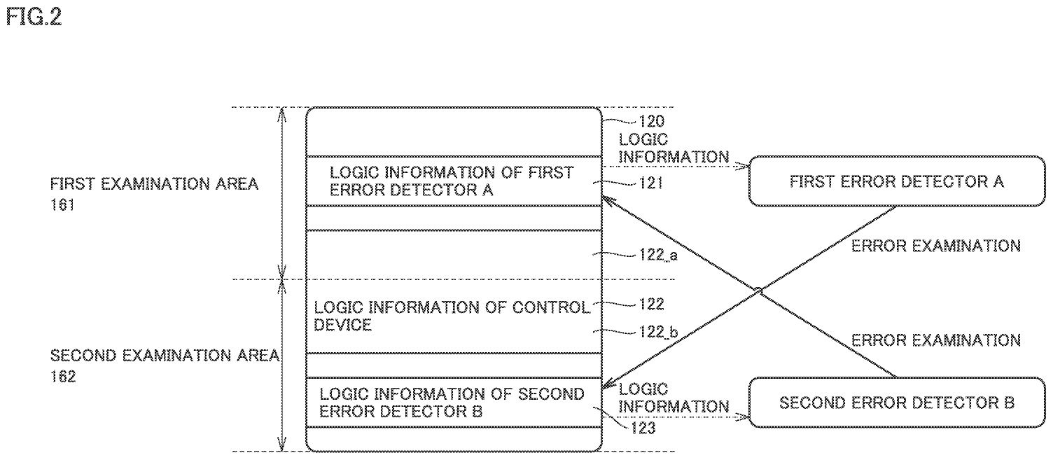

FIG. 2 is a diagram showing logic information items stored in configuration memory 120, and circuits configured with these logic information items.

Configuration memory 120 includes logic information for first error detector A, logic information for second error detector B, and logic information for control device 160.

Logic information 121 of first error detector A configures first error detector A. Logic information 123 of second error detector B configures second error detector B.

Configuration memory 120 is divided into a first examination area 161 and a second examination area 162. First examination area 161 stores logic information 121 of first error detector A, and a first half 122_a of the logic information of control device 160. Second examination area 162 stores logic information 123 of second error detector B, and a latter half 122_b of the logic information of control device 160.

First error detector A examines the information in second examination area 162 of configuration memory 120. Second error detector B examines the information in first examination area 161 of configuration memory 120.

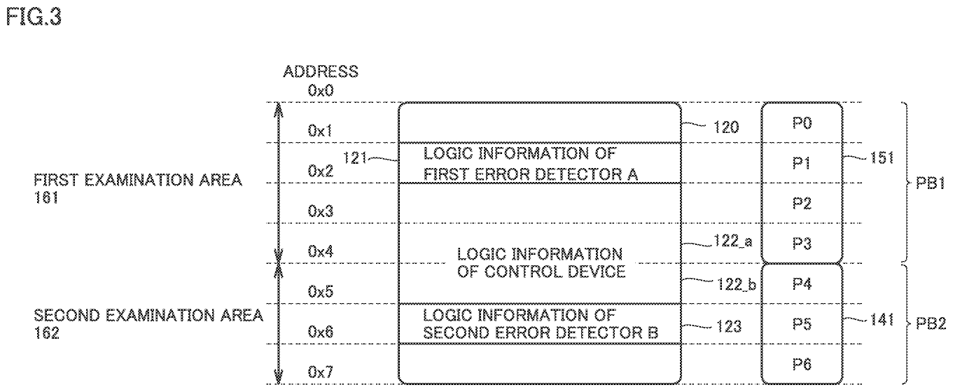

FIG. 3 is a diagram showing correspondences between logic information items in the configuration memory and parity bits in first error detection bit memory 141 and second error detection bit memory 151, according to Embodiment 1.

The location of logic information in configuration memory 120 is specified by an address.

Parity bits P0, P1, P2, and P3 for the logic information items in first examination area 161 are transferred from microcontroller 300 and stored to second error detection bit memory 151 included in second error detector B.

Parity bits P4, P5, and P6 for the logic information items in second examination area 162 are transferred from microcontroller 300 and stored to first error detection bit memory 141 included in first error detector A.

Using the logic information in second examination area 162 of configuration memory 120 and a corresponding parity bit in first error detection bit memory 141, first checker 143 included in first error detector A examines the logic information in second examination area 162 of configuration memory 120 as to whether the logic information has an error. Signal RA representing a result of the examination by first checker 143 is sent to microcontroller 300.

Using the logic information in first examination area 161 of configuration memory 120 and a corresponding parity bit in second error detection bit memory 151, second checker 153 included in second error detector B examines the logic information in first examination area 161 of configuration memory 120 as to whether the logic information has an error. Signal RB representing a result of the examination by second checker 153 is sent to microcontroller 300.

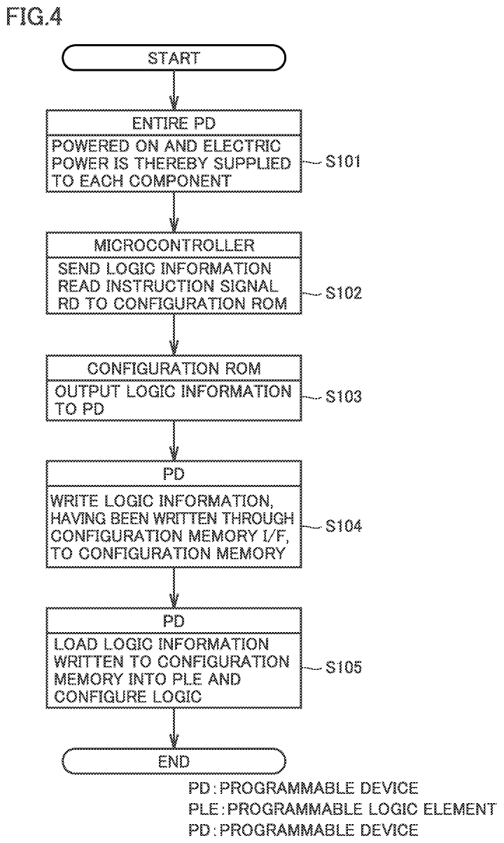

FIG. 4 is a flowchart illustrating a procedure for causing programmable device 100 to operate as a control device.

In step S101, programmable device 100 is powered on, and an electric power is thereby supplied to each component of programmable device 100.

In step S102, microcontroller 300 sends an instruction signal RD to configuration ROM 200.

In step S103, configuration ROM 200 outputs logic information items to programmable device 100.

In step S104, configuration memory interface 130 receives and writes the logic information items to configuration memory 120.

In step S105, configuration memory 120 loads the logic information items into programmable logic element group 110. This configures control device 160, first error detector A, and second error detector B, which are logics based on the logic information items.

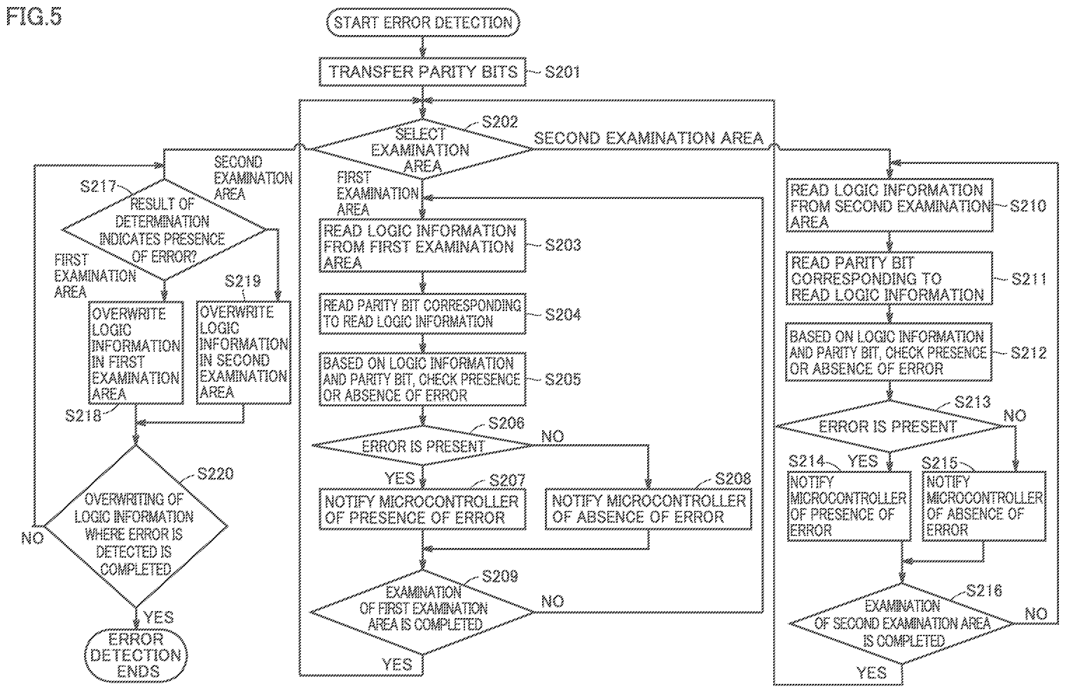

FIG. 5 is a flowchart illustrating a procedure for detecting an error in logic information in configuration memory 120.

In step S201, microcontroller 300 outputs parity bit group PB1 for the logic information items in first examination area 161 to second error detection bit memory 151. Microcontroller 300 outputs parity bit group PB2 for the logic information items in second examination area 162 to first error detection bit memory 141.

In step S202, microcontroller 300 selects an examination area. If first examination area 161 is selected, the process proceeds to step S203. If second examination area 162 is selected, the process proceeds to step S208. If no examination area is selected, the process proceeds to step S217.

In step S203, second error detector B reads unexamined logic information from first examination area 161.

In step S204, second error detector B reads from second error detection bit memory 151 a parity bit corresponding to the logic information read from first examination area 161.

In step S205, based on the logic information read from first examination area 161 and the parity bit read from second error detection bit memory 151, second error detector B performs error detection. If the logic information read from first examination area 161 has an error, second error detector B determines that an error is present, as a result of the examination.

In step S206, if the logic information has an error, the process proceeds to step S207. If the logic information has no error, the process proceeds to step S208.

In step S207, second error detector B notifies microcontroller 300 of the identifier (such as an address) of the logic information read from first examination area 161, and signal RB representing a result of determination indicating that the logic information has an error.

In step S208, second error detector B notifies microcontroller 300 of the identifier (such as an address) of the logic information read from first examination area 161, and signal RB representing a result of determination indicating that the logic information has no error.

In step S209, if examination of all the logic information items in first examination area 161 are completed, the process returns to step S202. If logic information the examination of which is not completed is present in first examination area 161, the process returns to step S203.

In step S210, first error detector A reads unexamined logic information from second examination area 162.

In step S211, first error detector A reads from first error detection bit memory 141 a parity bit corresponding the logic information read from second examination area 162.

In step S212, based on the logic information read from second examination area 162 and the parity bit read from first error detection bit memory 141, first error detector A performs error detection. If the logic information read from second examination area 162 has an error, first error detector A determines that an error is present, as a result of the examination.

In step S213, if the logic information has an error, the process proceeds to step S214. If the logic information has no error, the process proceeds to step S214.

In step S214, first error detector A notifies microcontroller 300 of the identifier (such as an address) of the logic information read from second examination area 162, and signal RA representing a result of determination indicating that the logic information has an error.

In step S215, first error detector A notifies microcontroller 300 of the identifier (such as an address) of the logic information read from second examination area 162, and signal RA representing a result of determination indicating that the logic information has no error.

In step S216, if examination of all the logic information items in second examination area 162 are completed, the process returns to step S202. If logic information the examination of which is not completed is present in second examination area 162, the process returns to step S210.

In step S217, if first examination area 161 includes logic information where an error is detected, the process proceeds to step S218. If second examination area 162 includes logic information where an error is detected, the process proceeds to step S219.

In step S218, microcontroller 300 controls programmable device 100 so that the logic information where an error is detected, which is included in first examination area 161 of configuration memory 120, is overwritten with corresponding logic information in configuration ROM 200.

In step S219, microcontroller 300 controls programmable device 100 so that the logic information where an error is detected, which is included in second examination area 162 of configuration memory 120, is overwritten with corresponding logic information in configuration ROM 200.

In step S220, if overwriting of the logic information where an error is detected is completed, the process ends. If the overwriting is not completed, the process returns to step S217.

As described above, according to the present embodiment, a malfunction of the control device can be prevented by detecting an error in logic information, rather than preventing the malfunction of the control device by multiplexing the control circuit, such as tripling thereof, as with the device disclosed in Japanese Patent No. 5699057 (PTL 1). This can prevent an increased circuit size.

According to the present embodiment, the error detectors making use of the programmable logic elements are utilized, and the error detection function will not be imparted even if the logic information data for the error detectors are destroyed.

According to the present embodiment, the configuration memory is divided into two areas, and logic information for one type of error detector is stored in each area. Second error detector B examines the area that includes the logic information of first error detector A, and first error detector A examines the area that includes the logic information of second error detector B. This can prevent the error detectors from malfunctioning due to destruction of the memory areas for the logic information items of the respective error detectors.

Furthermore, conventionally, a device is known which includes a hard-wired error detector resident outside the area for programmable logic elements (e.g., Japanese National Patent Publication No. 2005-505827). In contrast, according to the present embodiment, soft-error countermeasure is taken even with an FPGA (Field Programmable Gate Array) that is not hard-wired, and although the error detectors are configured by logic elements that are vulnerable to soft errors, a strong soft-error countermeasure is taken.

According to the present embodiment, when an error is detected while the programmable device is operating as the control device, the control device can be restored to normal operation by overwriting only an area of the configuration memory where data is destroyed, without shutting down the entirety of the control device.

### Variation of Embodiment 1

(1) In the present embodiment, the logic information in the configuration memory where an error is detected is overwritten with corresponding logic information in configuration ROM 200. However, the present invention is not limited thereto. If the logic information in the configuration memory where an error is detected is included in the first examination area, the entirety of the first examination area may be overwritten with the logic information in configuration ROM 200. If the logic information in the configuration memory where an error is detected is included in the second examination area, the entirety of the second examination area may be overwritten with the logic information in configuration ROM 200.

(2) In the present embodiment, logic information having an error in the configuration memory is overwritten after completion of examination of all the logic information items. However, the present invention is not limited thereto. The logic information may be overwritten instantly after an error is detected in the logic information.

(3) In the present embodiment, as shown in the flowchart of FIG. 5, the first examination area and the second examination area are checked at different time instants. However, the present invention is not limited thereto. The first examination area and the second examination area may be checked at the same time.

(4) In the present embodiment, two error detectors are provided and the configuration memory is formed of two examination areas. However, the present invention is not limited thereto. The configuration memory may include multiple logic information items that configure N error detectors i (i=1 to N) with programmable logic elements, and an error detector i may examine any logic information, other than the logic information of the error detector i.

(5) In the present embodiment, part of the logic information of the control device is included in the first examination area, and the rest of the logic information of the control device is included in the second examination area. However, the present invention is not limited thereto.

At least one of the first examination area and the second examination area may include the logic information of the control device. In other words, the first examination area and the second examination area may include the logic information of the control device, the first examination area may include the logic information of the control device, or the second examination area may include the logic information of the control device.

(6) In the present embodiment, the description has been described with reference to the use of a parity bit as an error detection bit. However, the present invention is not limited thereto. Any other type of error detection bit may be employed, insofar as the destruction of logic information stored in the configuration memory can be detected.

(7) In the present embodiment, when a result of detection by the error detector indicates that an error is present, the logic information in the configuration memory is determined to have an error and updated with external correct logic information. However, the present invention is not limited thereto. If the parity bit in the error detection bit memory is likely to have an error, the logic information in the configuration memory may be updated with external correct logic information and the parity bit in the error detection bit memory may be updated with an external correct parity bit. Alternatively, if the error detector can detect whether an error is present in logic information in the configuration memory or a parity bit in the error detection bit memory, whichever of the logic information or the parity bit that has an error may be updated with correct data.

### Embodiments 2

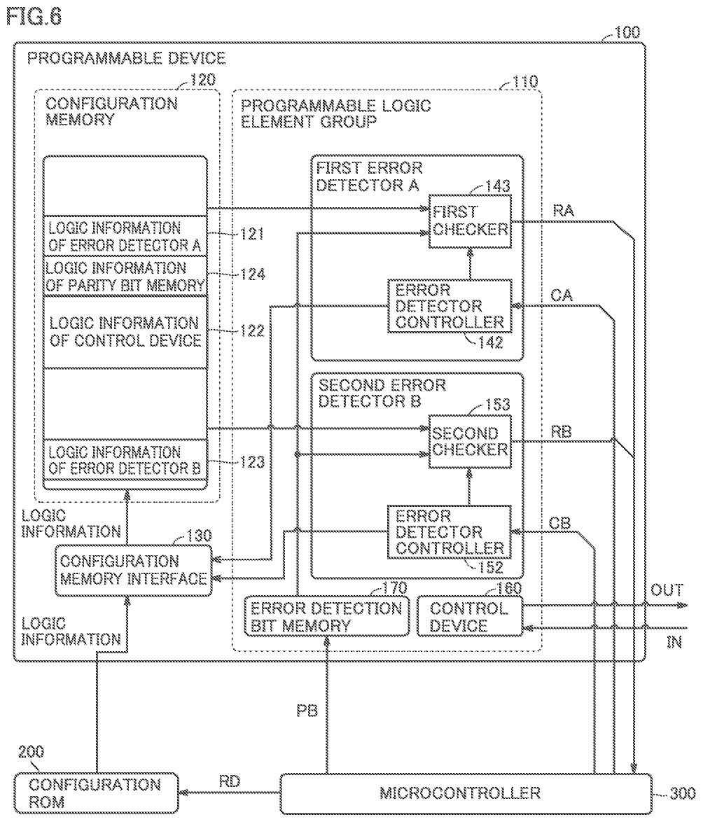

FIG. 6 is a diagram showing a configuration of a programmable device 100 according to Embodiments 2.

Programmable device 100 according to Embodiments 2 differs from programmable device 100 according to Embodiment 1 as follows:

In programmable device 100 according to Embodiments 2, a first error detector A does not include a first error detection bit memory 141, and a second error detector B does not include a second error detection bit memory 151. In programmable device 100 according to Embodiments 2, programmable logic elements included in a programmable logic element group 110 configure an error detection bit memory 170, in addition to first error detector A, second error detector B, and control device 160.

A microcontroller 300 directly writes a parity bit group PB for all the logic information in configuration memory 120 to error detection bit memory 170.

Error detection bit memory 170 stores parity bit group PB1 output from microcontroller 300.

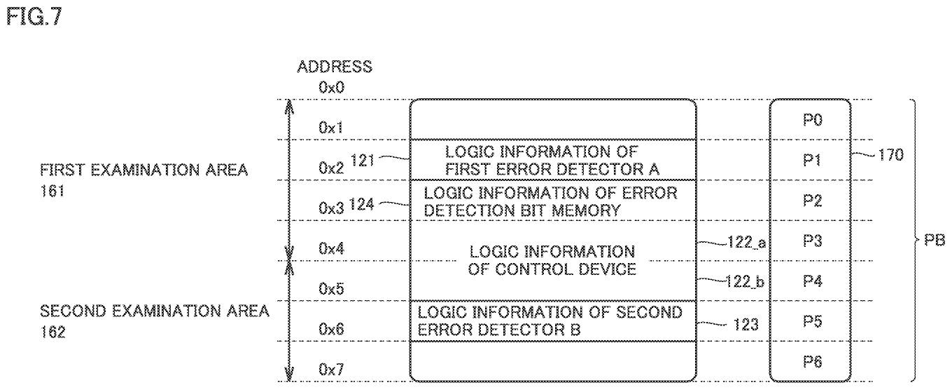

FIG. 7 is a diagram showing correspondences between logic information items in the configuration memory 120 and parity bits in error detection bit memory 170, according to Embodiments 2.

As with Embodiment 1, configuration memory 120 includes logic information for first error detector A, logic information for second error detector B, and logic information for control device 160. Configuration memory 120 further includes logic information for error detection bit memory 170.

The logic information of error detection bit memory 170 configures error detection bit memory 170.

Configuration memory 120 is divided into a first examination area 161 and a second examination area 162. First examination area 161 stores logic information 121 for first error detector A, logic information for error detection bit memory 170, and a first half 122_a of logic information for control device 160. Second examination area 162 stores logic information 123 for second error detector B, and a latter half 122_b of the logic information for control device 160.

First error detector A examines the logic information in second examination area 162 of configuration memory 120. Second error detector B examines the logic information in first examination area 161 of configuration memory 120.

Parity bits P0, P1, P2, P3 for the logic information items in first examination area 161, and parity bits P4, P5, and P6 for the logic information items in second examination area 162 are transferred from microcontroller 300 and stored to error detection bit memory 170.

Using the logic information in second examination area 162 of configuration memory 120 and a corresponding parity bit in an error detection bit memory 171, first checker 143 included in first error detector A performs an error detection process. A signal RA representing a result of examination by first checker 143 is sent to microcontroller 300.

Using the logic information in first examination area 161 of configuration memory 120 and a corresponding parity bit in error detection bit memory 171, second checker 153 included in second error detector B performs an error detection process. A signal RB representing a result of examination by second checker 153 is sent to microcontroller 300.

If an error is detected, the following cases are possible: examined logic information in configuration memory 120 has an error; the logic information configuring the error detection bit memory 170 in configuration memory 120 has an error; and a parity bit in error detection bit memory 170 has an error. If an error is detected, microcontroller 300 updates, with correct logic information in a configuration ROM, the examined logic information in configuration memory 120 and the logic information configuring the error detection bit memory 170, and updates the parity bit in error detection bit memory 170 with a correct parity bit in microcontroller 300.

Among an examined logic information and a parity bit in an error detection bit memory, if the error detector detects an error in the examined logic information microcontroller 300 may update the examined logic information in configuration memory 120 with correct logic information in the configuration ROM. Among examined logic information and a parity bit in an error detection bit memory, if the error detector detects an error in the parity bit in the error detection bit memory, microcontroller 300 may update, with correct logic information in the configuration ROM, the logic information configuring the error detection bit memory 170 in configuration memory 120, and update the parity bit in error detection bit memory 170 with a correct parity bit in microcontroller 300.

According to the present embodiment, the parity bits for logic information items in the configuration memory which are used by the first error detector and the second error detector can be stored in a common memory.

### Embodiments 3

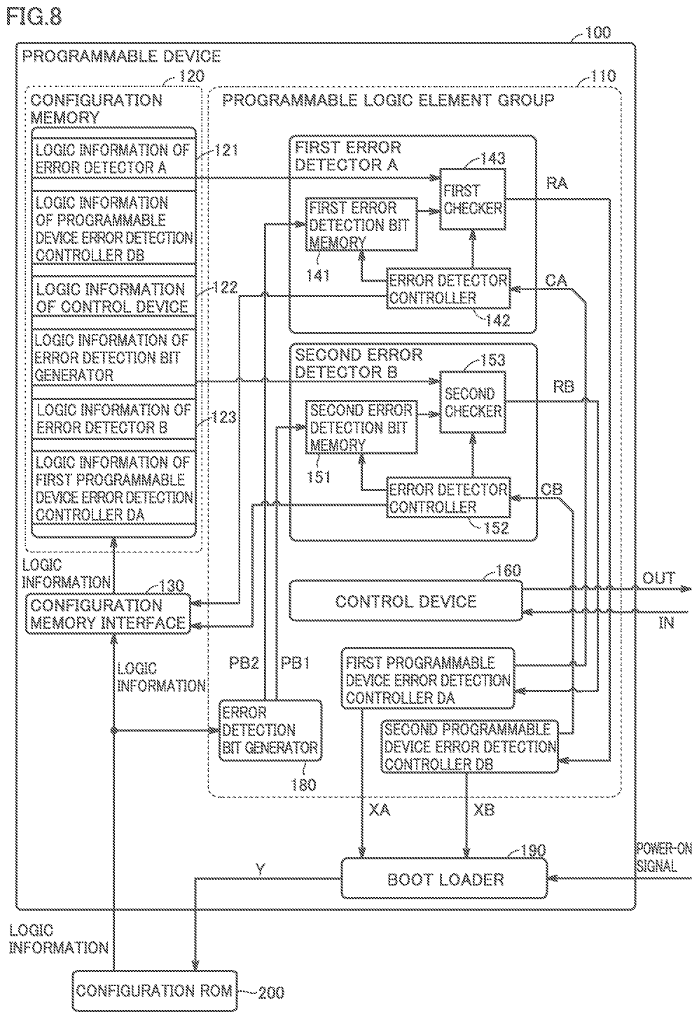

FIG. 8 is a diagram showing a configuration of a programmable device 100 according to Embodiments 3.

Programmable device 100 according to Embodiments 3 differs from programmable device 100 according to Embodiment 1 as follows:

Programmable device 100 according to Embodiments 3 includes programmable logic elements forming a programmable logic element group 110 that configure an error detection bit generator 180, a first programmable device error detection controller DA, and a second programmable device error detection controller DB, in addition to a first error detector A, a second error detector B, and a control device 160.

Error detection bit generator 180 generates parity bits for logic information items that are sent from configuration ROM 200 to configuration memory 120. Error detection bit generator 180 writes the parity bits for the logic information items in second examination area 162 to first error detection bit memory 141. Error detection bit generator 180 writes the parity bits for the logic information items in first examination area 161 to second error detection bit memory 151.

First programmable device error detection controller DA controls first error detector A. Second programmable device error detection controller DB controls second error detector B.

Programmable device 100 according to Embodiments 3 includes a boot loader 190. Boot loader 190, as it receives a power-ON signal, outputs a control signal Y to configuration ROM 200, thereby causing the logic information items in configuration ROM 200 to be transferred to configuration memory 120 via configuration memory interface 130.

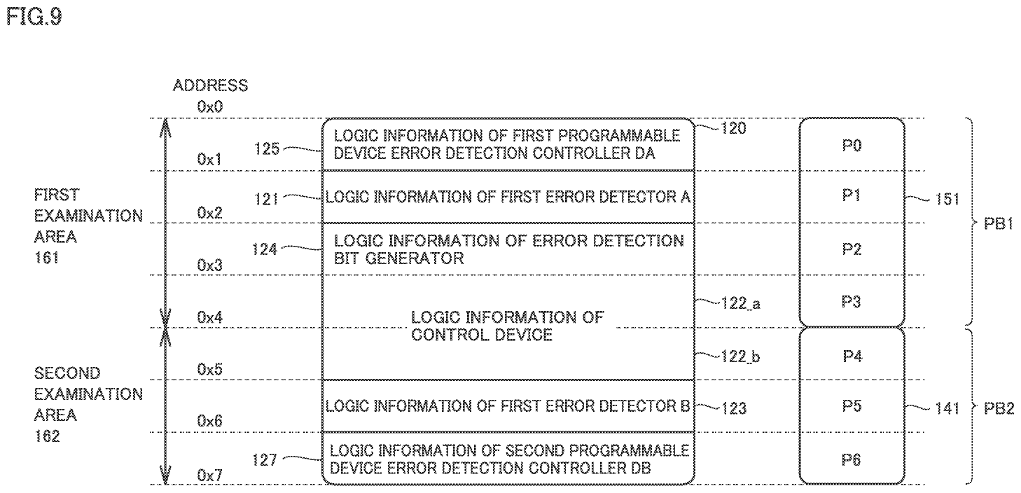

FIG. 9 is a diagram showing correspondences between logic information items in a configuration memory 120 and parity bits in error detection bit memory 170, according to Embodiments 3.

As with Embodiment 1, configuration memory 120 includes logic information for first error detector A, logic information for second error detector B, and logic information for control device 160. Configuration memory 120 further includes logic information for error detection bit generator 180, logic information for first programmable device error detection controller DA, and logic information for second programmable device error detection controller DB.

The logic information of error detection bit generator 180 configures error detection bit generator 180. The logic information of first programmable device error detection controller DA configures first programmable device error detection controller DA. The logic information of second programmable device error detection controller DB configures second programmable device error detection controller DB.

Configuration memory 120 is divided into a first examination area 161 and a second examination area 162. First examination area 161 stores logic information 125 of first programmable device error detection controller DA, logic information 121 of first error detector A, the logic information of error detection bit generator 180, and a first half 122_a of the logic information of control device 160.

Second examination area 162 stores logic information 123 of second error detector B, a latter half 122_b of the logic information of control device 160, and logic information 127 of second programmable device error detection controller DB.

First error detector A examines the logic information items in second examination area 162 of configuration memory 120. Second error detector B examines the logic information items in first examination area 161 of configuration memory 120.

Parity bits P0, P1, P2, and P3 for the logic information items in first examination area 161 are transferred from microcontroller 300 and stored to second error detection bit memory 151. Parity bits P4, P5, and P6 for the logic information items in second examination area 162 are transferred from microcontroller 300 and stored to first error detection bit memory 141.

Using the logic information in second examination area 162 of configuration memory 120 and a corresponding parity bit in error detection bit memory 171, first checker 143 included in first error detector A performs an error detection process, in accordance with a control signal CA from first programmable device error detection controller DA. A signal RA representing a result of examination by first checker 143 is sent to second programmable device error detection controller DB.

Using the logic information in first examination area 161 of configuration memory 120 and a corresponding parity bit in error detection bit memory 171, a second checker 153 included in second error detector B performs an error detection process, in accordance with a control signal CB from second programmable device error detection controller DB. A signal RB representing a result of examination by second checker 153 is sent to first programmable device error detection controller DA.

First programmable device error detection controller DA outputs a control signal XA to boot loader 190 so that the logic information in first examination area 161 where an error is detected is updated with logic information in configuration ROM 200. Boot loader 190 outputs a control signal Y instructing transferring to configuration ROM 200 the logic information in first examination area 161 where an error is detected.

Second programmable device error detection controller DB outputs a control signal XB to boot loader 190 so that the logic information in second examination area 162 where an error is detected is updated with logic information in configuration ROM 200. Boot loader 190 outputs a control signal Y instructing transferring to configuration ROM 200 the logic information in second examination area 162 where an error is detected.

According to the present embodiment, the programmable device includes the error detection bit generator, the first programmable device error detection controller, the second programmable device error detector, and the boot loader. This allows the programmable device to detect an error in logic information in the configuration memory and update the logic information where an error is detected with correct logic information, independent of the microcontroller.

### Embodiments 4

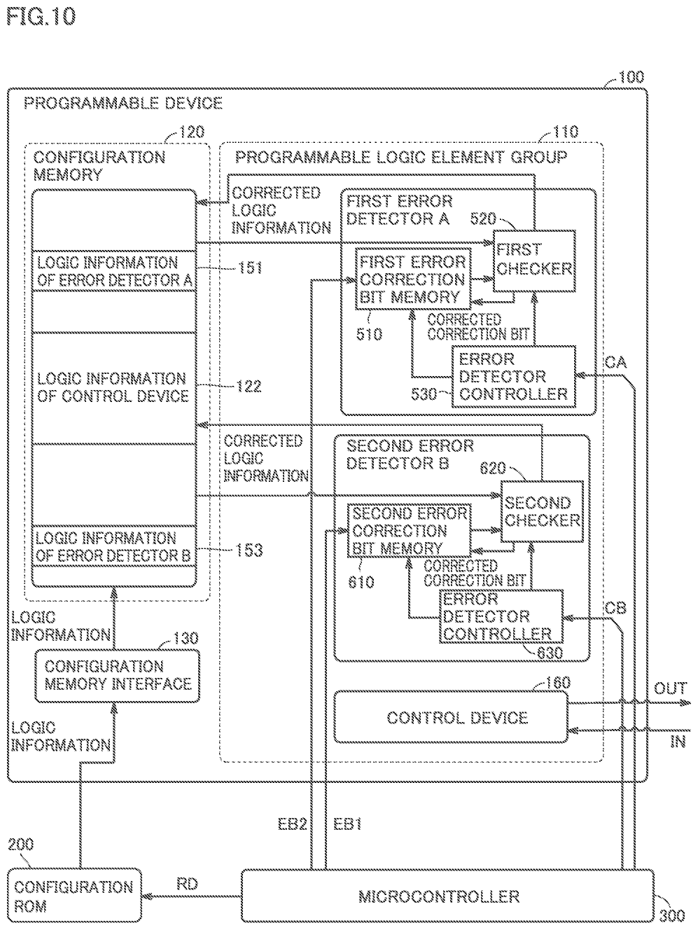

FIG. 10 is a diagram showing a configuration of a programmable device 100 according to Embodiments 4.

Programmable device 100 according to Embodiments 4 differs from programmable device 100 according to Embodiment 1 as follows:

First error detector A includes a first error correction bit memory 510, a first checker 520, and an error detector controller 530. Upon receipt of a control signal CA from microcontroller 300, error detector controller 530 controls first error correction bit memory 510 and first checker 520.

Second error detector B includes a second error correction bit memory 610, a second checker 620, and an error detector controller 630. Upon receipt of control signal CA from microcontroller 300, error detector controller 630 controls second error correction bit memory 610 and second checker 620.

Microcontroller 300 outputs an error correction bit group EB1 for logic information items in first examination area 161 to second error correction bit memory 610. Microcontroller 300 outputs an error correction bit group EB2 for logic information items in second examination area 162 to first error correction bit memory 510.

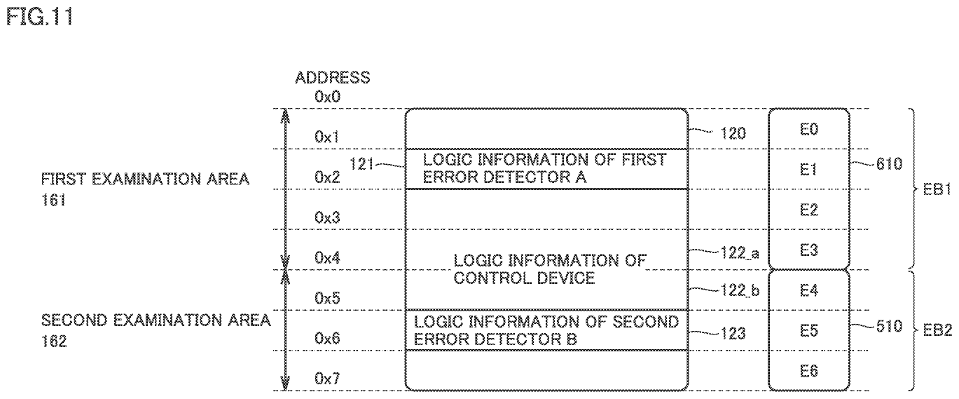

FIG. 11 is a diagram showing correspondences between logic information items in a configuration memory and parity bits in error detection bit memory 170, according to Embodiments 4.

As with Embodiment 1, configuration memory 120 includes logic information for first error detector A, logic information for second error detector B, and logic information for control device 160.

Configuration memory 120 is divided into a first examination area 161 and a second examination area 162. First examination area 161 stores logic information 121 for first error detector A and a first half 122_a of the logic information for control device 160.

Second examination area 162stores logic information 123 for second error detector B, and a latter half 122_b of the logic information for control device 160.

First error detector A examines the information in second examination area 162 of configuration memory 120. Second error detector B examines the information in first examination area 161 of configuration memory 120.

Error correction bits E0, E1, E2, and E3 for the logic information items in first examination area 161 are transferred from microcontroller 300 and stored to second error correction bit memory 610. Error correction bits E4, E5, and E6 for the logic information items in second examination area 162 are transferred from microcontroller 300 and stored to first error correction bit memory 510. Microcontroller 300 error-correction encodes the logic information, thereby generating an error correction bit. The logic information and a corresponding error correction bit configure an error correction code. Examples of the error correction code include a Reed-Solomon code.

Using the logic information in second examination area 162 of configuration memory 120 and a corresponding error correction bit in first error correction bit memory 510, first checker 520 included in first error detector A examines the logic information in second examination area 162 of configuration memory 120 as to whether the logic information has an error. If the logic information has an error, first checker 520 corrects the error and overwrites a corresponding area of configuration memory 120 with the corrected logic information. Furthermore, first checker 520 overwrites first error correction bit memory 510 with a normal error correction bit corresponding to the logic information an error in which has been corrected.

Using the logic information in first examination area 161 of configuration memory 120 and a corresponding error correction bit in second error correction bit memory 610, second checker 620 included in second error detector B examines the logic information in first examination area 161 of configuration memory 120 as to whether the logic information has an error. If the logic information has an error, second checker 620 corrects the error and overwrites a corresponding area of configuration memory 120 with the corrected logic information. Furthermore, second checker 620 overwrites second error correction bit memory 610 with a normal error correction bit corresponding to the logic information an error in which has been corrected.

According to the present embodiment, when data in the configuration memory is destroyed, the checker in the programmable device corrects an error of the logic information in the configuration memory. This allows the data in the configuration memory to be successfully restored, independent of the microcontroller.

The presently disclosed embodiments should be considered in all aspects as illustrative and not restrictive. The scope of the present invention is indicated by the appended claims, rather than by the description above, and all changes that come within the scope of the claims and the meaning and range of equivalency of the claims are intended to be embraced within their scope.

### REFERENCE SIGNS LIST

100 programmable device; 110 programmable logic element group; 120 configuration memory; 130 configuration memory interface; 141 first error detection bit memory; 151 second error detection bit memory; 170 error detection bit memory; 142, 152, 530, 630 error detector controller; 143, 520 first checker; 153, 620 second checker; 160 control device; 180 error detection bit generator;

190 boot loader; 200 configuration ROM; 300 microcontroller; 510 first error correction bit memory; 610 second error correction bit memory; A first error detector; B second error detector; DA first programmable device error detection controller; and DB second programmable device error detection controller.

1. A programmable device, comprising:
a plurality of programmable logic elements; and
a configuration memory to store logic information for circuits configured by the plurality of programmable logic elements, wherein
the configuration memory includes first logic information which configures a first error detector with a programmable logic element among the plurality of programmable logic elements,
the first error detector examines logic information other than the first logic information.

2. The programmable device according to claim 1, wherein
the configuration memory includes second logic information which configures a second error detector with a programmable logic element among the plurality of programmable logic elements,
the first error detector examines an area that includes the second logic information, the first error detector not including the first logic information, and
the second error detector examines an area that includes the first logic information, the second error detector not including the second logic information.

3. The programmable device according to claim 1, wherein
the configuration memory includes a plurality of logic information items that configure a plurality of error detectors, including the first error detector, with programmable logic elements among the plurality of programmable logic elements, and
each error detector, among the plurality of error detectors, examines logic information other than logic information for the error detector.

4. The programmable device according to claim 2, wherein
the configuration memory includes third logic information that configures a control device with a programmable logic element among the plurality of programmable logic elements,
the configuration memory includes a first examination area and a second examination area, the first examination area including the first logic information, the second examination area including the second logic information, at least one of the first examination area or the second examination area including the third logic information,
the first error detector examines logic information in the second examination area, and
the second error detector examines logic information in the first examination area.

5. The programmable device according to claim 4, wherein
the first error detector includes a first checker and a first error detection bit memory,
the second error detector includes a second checker and a second error detection bit memory,
the first error detection bit memory stores an error detection bit for the logic information in the second examination area,
the second error detection bit memory stores an error detection bit for the logic information in the first examination area,
based on the logic information in the second examination area and the error detection bit in the first error detection bit memory, the first checker performs an error detection process, and
based on the logic information in the first examination area and the error detection bit in the second error detection bit memory, the second checker performs an error detection process.

6. The programmabled device according to claim 5, wherein
the first checker and the second checker each output a result of detection to a microcontroller.

7. The programmable device according to claim 5, wherein
the configuration memory updates the logic information where an error is detected with logic information externally transferred to the configuration memory.

8. The programmable device according to claim 5, wherein
the error detection bit in the first error detection bit memory and the error detection bit in the second error detection bit memory are transferred from a microcontroller for storage.

9. The programmable device according to claim 5, wherein
the configuration memory includes fourth logic information that configures an error defection bit generator with it programmable logic element among the plurality of programmable logic elements, and
the error detection bit generator generates the error detection bit for the logic information in the first examination area from logice information externally transferred to the first examination area, and transfers the error detection bit to the second error detection bit memory, and generates the error detection bit for the logic information in the second examination area from logic information externally transferred to the second examination area, and transfers the error detection bit to the first error detection bit memory.

10. The programmable device according to claim 5, wherein
the configuration memory includes fifth logic information which configures a first programmable device error detection controller with a programmable logic element among the plurality of programmable logic elements, and sixth logic information which configures a second programmable device error detection controller with a programmable logic element among the plurality of programmable logic elements,
the first checker performs the error detection process in accordance with control by the first programmable device error detection controller, and outputs a result of detection to the second programmable device error detection controller, and
the second checker performs the error detection process in accordance with control by the second programmable device error detection controller, and outputs a result of detoction to the first programmable device error detection controller.

11. The programmable device according to claim 10, wherein
the first programmable device error detection controller controls the programmable device so that the logic information in the first examination area where an error is detected is updated with logic information in an external ROM, and
the second programmable device error detection controller controls the programmable device so that the logic information in the second examination area where an error is detected is updated with logic information in an external ROM.

12. The programmable device according to claim 11, comprising
a boot loader to control the programmable device so that the logic information stored in the external ROM is transferred to the configuration memory.

13. The programmable device according to claim 4, wherein
the first error detector includes a first checker and a first error correction bit memory,
the second error detector includes a second checker and a second error correction bit memory,
the first error correction bit memory stores an error correction bit generated by error-correction encoding the logic information in the second examination area,
the second error correction bit memory stores an error correction bit generated by error-correction encoding the logic information in the first examination area,
based on the logic information in the second examination area and the error correction bit in the first error correction bit memory, the first checker corrects an error of the logic information in the second examination area, and updates the logic information in the second examination area of the configuration memory with the logic information the error in which has been corrected, and
based on the logic information in the first examination area and the error correction bit in the second error correction bit memory, the second checker corrects an error of the logic information in the first examination area, and updates the logic information in the first examination area of the configuration memory with the logic information the error in which has been corrected.

14. The programmable device according to claim 4, wherein
the first error detector includes a first checker and a first error detection bit memory,
the second error detector includes a second checker and a second error detection bit memory,
the first error detection bit memory stores an error detection bit for the logic information in the second examination area,
the second error detection bit memory stores an error detection bit for the logic information in the first examination area,
based on the logic information in the second examination area and the error detection bit in the first error detection bit memory, the first checker detects whether the logic information in the second examination area has an error,
based on the logic information in the first examination area and the error detection bit in the second error detection bit memory, the second checker detects whether the logic information in the first examination area has an error.

15. The programmable device according to claim 4, wherein
the cofiguration memory includes seventh logic information that configures an error detection bit memory with a programmable logic element among the plurality of programmable logic elements,
the first error detector includes a first checker,
the second error detector includes a second checker,
the error detection bit memory stores error detection bit for the logic information in the first examination area transferred from a microcontroller, and an error detection bit for the logic information in the second examination area transferred from the microcontroller,
based on the logic information in the second examination area and the error detection bit for the logic information in the second examination area of the error detection bit memory, the first checker performs an error detection process, and
based on the logic information in the first examination area and the error detection bit for the logic information in the first examination area of the error detection bit memory, the second checker performs an error detection process.
